(19) United States
(12) Patent Application Publication
(10) Pub. No.: US 2025/0140653 A1
(43) Pub. Date: May 1, 2025

(54) HYBRID QUAD FLAT PACKAGE ELECTRONIC DEVICE

(71) Applicant: Texas Instruments Incorporated, Dallas, TX (US)

(72) Inventors: Anindya Poddar, Sunnyvale, CA (US); Ashok Prabhu, San Jose, CA (US); Hau Nguyen, San Jose, CA (US); Kurt Sincerbox, San Jose, CA (US); Makoto Shibuya, Tokyo (JP)

(21) Appl. No.: 18/494,027

(22) Filed: Oct. 25, 2023

(51) Int. Cl. H01L 23/495; H01L 21/48; H01L 21/56; H01L 23/00; H01L 23/31

(52) U.S. Cl. CPC H01L 23/49541; H01L 21/4842; H01L 21/561; H01L 23/3121; H01L 24/05; H01L 24/32; H01L 24/48; H01L 24/49; H01L 24/73; H01L 24/83; H01L 24/92; H01L 24/97; H01L 2224/05624; H01L 2224/05647; H01L 2224/32245; H01L 2224/48091; H01L 2224/48108; H01L 2224/48245; H01L 2224/48465; H01L 2224/49171; H01L 2224/73265; H01L 2224/83815; H01L 2224/83862; H01L 2224/83874; H01L 2224/92247; H01L 2224/97

(57) ABSTRACT

An electronic device includes opposite first and second sides, opposite third and fourth sides spaced apart along a first direction, and opposite fifth and sixth sides spaced apart along a second direction orthogonal to the first direction, the first and second sides being spaced apart along a third direction orthogonal to the first and second directions. The electronic device includes a molded package, first leads exposed outside the molded package along the first side, and the first leads extending outward from the molded package along a respective one of the third and fourth sides, and second leads exposed outside the molded package along the first side, the second leads having a lateral side exposed outside the molded package along a respective one of the fifth and sixth sides, and the lateral side of the individual second leads being flush with a respective side of the molded package.

### BACKGROUND

Quad flat pack electronic devices have become a popular form for compact electronic circuitry that can be soldered to a printed circuit board. Quad flat no-lead (QFN) packaged devices have flush leads on four lateral sides that are created during package singulation by sawing after strip molding. However, the molding and package singulation steps are significant contributors to total package assembly cost. For example, strip or panel molding often requires film assisted molding (FAM). In addition, this approach requires separating individual devices from a lead frame panel array by cutting operations that have low package singulation throughput and replacing worn cutting blades for sawing through a lead frame and mold compound is costly. Other quad flat devices have stub leads protruding from the four lateral sides, but this packaging approach requires individual mold cavities to create over molded packages for each device in a panel array or strip, and a different mold and punch equipment for device separation must be used for each different package size.

### SUMMARY

In one aspect, an electronic device includes opposite first and second sides, opposite third and fourth sides spaced apart from one another along a first direction, and opposite fifth and sixth sides spaced apart from one another along a second direction that is orthogonal to the first direction, where the first and second sides are spaced apart from one another along a third direction that is orthogonal to the first and second directions. The electronic device includes a molded package structure as well as conductive metal first and second leads exposed outside the molded package structure along the first side. Individual ones of the first leads extend outward from the molded package structure along a respective one of the third and fourth sides. Individual ones of the second leads have a lateral side exposed outside the molded package structure along a respective one of the fifth and sixth sides, and the lateral side of the individual second leads is flush with a respective side of the molded package structure along the respective one of the fifth and sixth sides.

In another aspect, a method of fabricating an electronic device includes mounting a semiconductor die in a unit area of a lead frame, electrically connecting the semiconductor die to prospective first leads along two opposite lateral sides of the unit area that are spaced apart from one another along a first direction, electrically connecting the semiconductor die to prospective second leads along two opposite lateral ends of the unit area that are spaced apart from one another along a second direction that is orthogonal to the first direction, forming a molded package structure that extends through multiple unit areas along a column of the lead frame, exposes portions of the prospective first leads in the unit area, and encloses the prospective second leads in the unit area, separating the column from an adjacent second column of the lead frame along the second direction to form first leads along the two opposite lateral sides of the unit area, and separating an electronic device of the unit area from the lead frame along the first direction to cut through the molded package structure and the prospective second leads to form second leads along the two opposite lateral ends of the unit area.

In another aspect, a lead frame includes unit areas arranged in an array with rows along a first direction and columns along an orthogonal second direction, the respective unit areas having a die attach pad, prospective first leads along two opposite lateral sides of the unit area that are spaced apart from one another along the first direction, and prospective second leads along two opposite lateral ends of the unit area that are spaced apart from one another along the second direction, first tie bars connected to the prospective first leads of the unit areas along a column of the array, second tie bars connected to the prospective second leads along adjacent rows of the array, and third tie bars connected between the die attach pad and an adjacent one of the second tie bars of the unit areas along the column of the array.

### BRIEF DESCRIPTION OF THE DRAWINGS

FIG. 1 is a top perspective view of an electronic device with flush leads along opposite lateral ends and stub leads along opposite lateral sides.

FIG. 1A is a bottom perspective view of the electronic device of FIG. 1.

FIG. 1B is a bottom perspective view of another example electronic device with flush leads along opposite lateral ends and stub leads along opposite lateral sides.

FIG. 1C is a bottom perspective view of yet another example electronic device with flush leads along opposite lateral ends and stub leads along opposite lateral sides.

FIG. 2 is a flow diagram showing a method for making an electronic device according to another aspect.

FIG. 3 is a top plan view of a lead frame panel array.

FIG. 3A is a partial top perspective view of a portion of the lead frame panel array of FIG. 3.

FIG. 4 is a partial top perspective view of a die attach process that attaches semiconductor dies to unit areas of the lead frame panel array of FIGS. 3 and 3A.

FIG. 5 is a partial top perspective view of the lead frame panel array undergoing a wirebonding electrical connection process.

FIG. 6 is a partial top perspective view of the lead frame panel array undergoing a column molding process.

FIG. 7 is a partial top perspective view of the lead frame panel array undergoing a column direction separation process.

FIG. 8 is a partial top perspective view of the lead frame panel array undergoing a row direction separation process.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”. “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means+/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc. may be referred to herein as first, second, third, etc., such as first and second terminals, first, second, and third, wells, etc., for case of description in connection with a particular drawing, where such are not to be construed as limiting with respect to the claims. Various disclosed structures and methods of the present disclosure may be beneficially applied to manufacturing an electronic device such as an integrated circuit. While such examples may be expected to provide various improvements, no particular result is a requirement of the present disclosure unless explicitly recited in a particular claim.

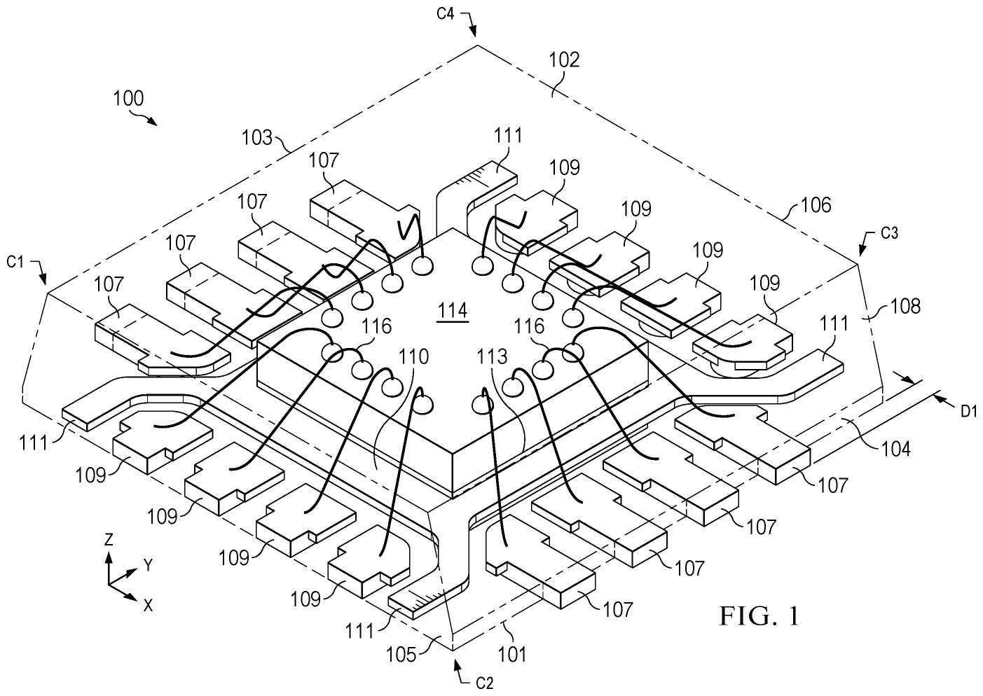

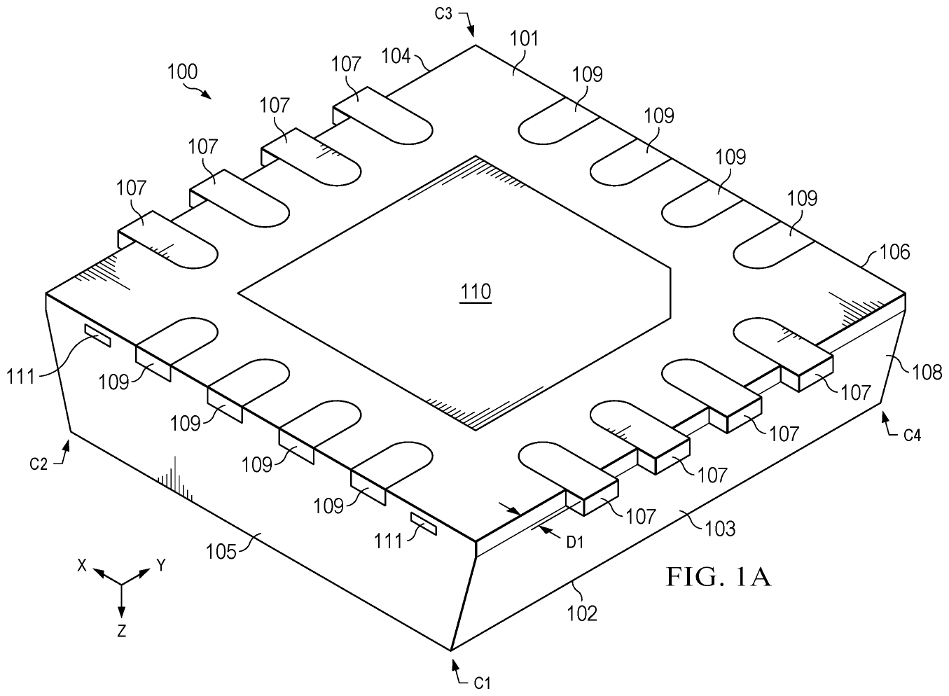

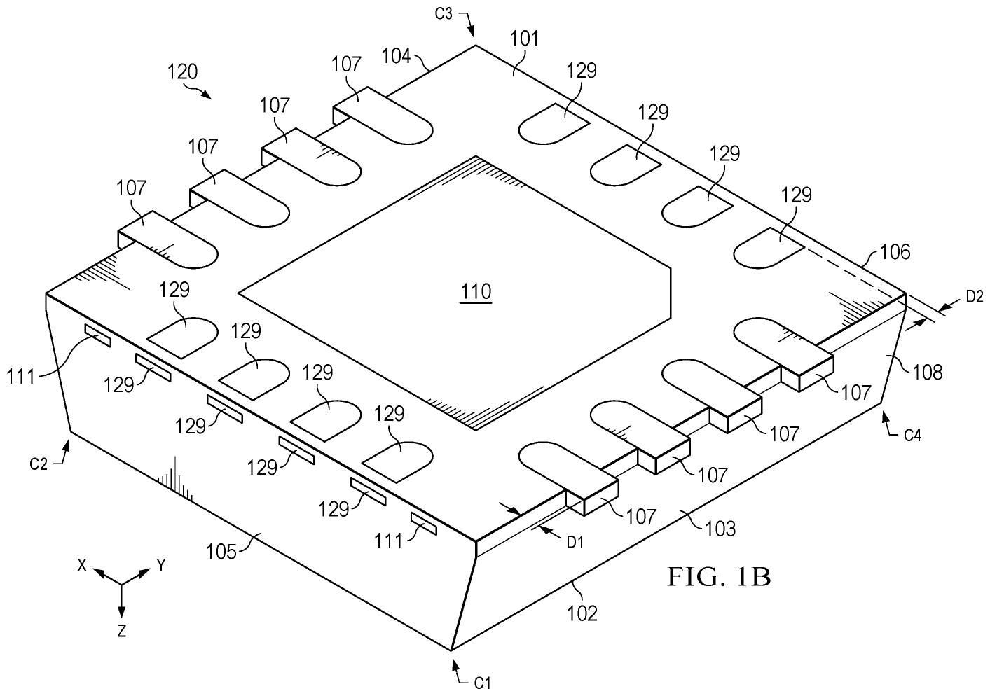

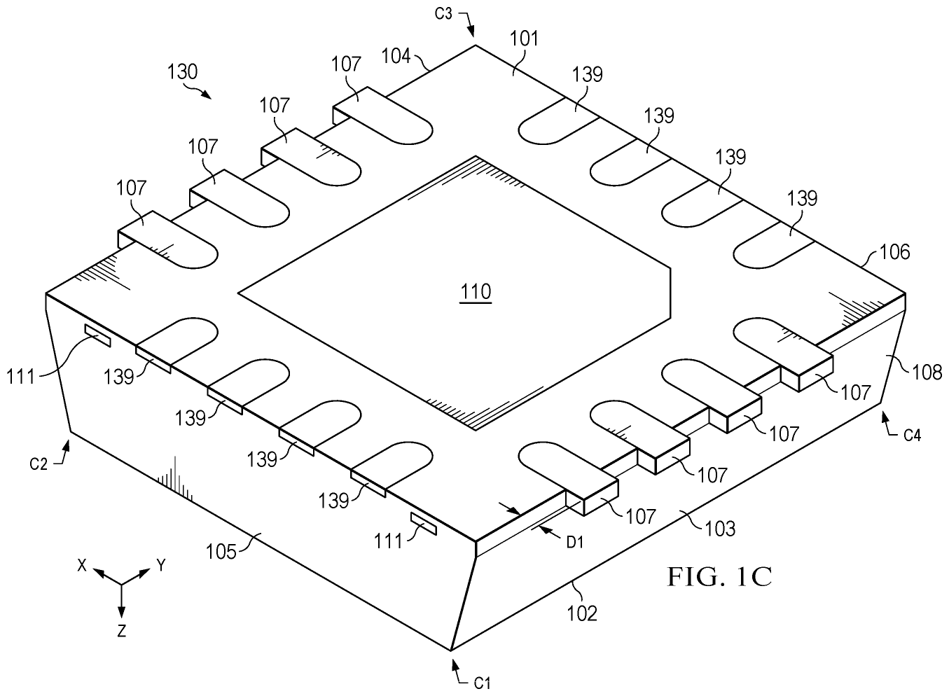

FIGS. 1 and 1A show an example quad flat electronic device 100 in an example position in a three-dimensional space with a first direction X, a perpendicular (orthogonal) second direction Y, and a third direction Z that is perpendicular (orthogonal) to the respective first and second directions X and Y. Structures or features along any two of these directions are orthogonal to one another. The electronic device 100 has opposite first and second (e.g., bottom and top) sides 101 and 102, respectively, which are spaced apart from one another along the third direction Z in the illustrated position. The electronic device 100 also has opposite third and fourth sides 103 and 104 (e.g., lateral sides) that are spaced apart from one another along the first direction X, and fifth and sixth sides 105 and 106 that are spaced apart from one another along the second direction Y in the illustrated position.

The electronic device has a hybrid quad flat package arrangement with conductive metal first leads 107 (e.g., also referred to as stub leads) exposed outside a molded package structure 108 along the bottom or first side 101. The individual first leads 107 extend outward from the molded package structure 108 by a first spacing distance D1 along a respective one of the third and fourth sides 103 and 104. In various example implementations, the electronic device 100 can have any integer number of one or more instances of the first lead 107 extending outward along the first direction X from the molded package structure 108 along the third side 103 and one or more instances of the first lead 107 extending outward along the first direction X from the molded package structure 108 along the fourth side 104.

The illustrated electronic device 100 in FIGS. 1 and 1A is a 16 lead device (e.g., having lateral dimensions of approximately 3 mm×3 millimeters) having a first set (e.g., 4 instances) of the first leads 107 that are spaced apart from one another along the second direction Y and extend outward along the first direction X from the molded package structure 108 along the third side 103. The first set of the first leads 107 have respective lateral sides exposed outside the molded package structure 108 along the third side 103.

Along the fourth side 104, the illustrated electronic device 100 has a second set (e.g., 4 instances) of the first leads 107 that are spaced apart from one another along the second direction Y and extend outward along the first direction X from the molded package structure 108. The second set of the first leads 107 have respective lateral sides exposed outside the molded package structure 108 along the fourth side 104. The molded package structure 108 in one example has generally flat lateral sides along the third and fourth sides of the electronic device 100, although not a requirement of all possible implementations. The lateral sides of the molded package structure 108 in one example have slight draft angles with respect to the third direction Z in the illustrated orientation, for example, corresponding to draft angles of a mold cavity used in creating the molded package structure 108. In the example of FIGS. 1 and 1A, the first leads 107 have a bottom side exposed outside the molded package structure 108 along the first side 101, and the first leads 107 have a uniform thickness along the third direction Z.

The hybrid quad flat package electronic device 100 in this example also includes conductive metal second leads 109, also referred to as flush leads, with bottom sides exposed outside the molded package structure 108 along the first (e.g., bottom) side 101. The individual second leads 109 have a lateral side exposed outside the molded package structure 108 along a respective one of the fifth and sixth sides 105 and 106. In addition, the lateral side of the individual second leads 109 is flush with a respective side of the molded package structure 108 along the respective one of the fifth and sixth sides 105 and 106. In various example implementations, the electronic device 100 can have any integer number of one or more instances of the second lead 109 along the fifth side 105 and one or more instances of the second lead along the sixth side 106.

The lateral sides of the molded package structure 108 along the fifth and sixth sides 105 and 106 in one example are substantially planar lying in parallel respective X-Z planes and the illustrated orientation, although not a requirement of all possible implementations. The molded package structure 108 is approximately rectangular with four lateral corners including a first corner C1 proximate the intersection of the respective third and fifth sides 103 and 105, a second corner C2 proximate the intersection of the respective fourth and fifth sides 104 and 105, a third corner C3 proximate the intersection of the respective fourth and sixth sides 104 and 106, and a fourth corner C4 proximate the intersection of the third and sixth sides 103 and 106.

The electronic device 100 in FIGS. 1 and 1A has a first set of four instances of the second leads 109 that are spaced apart from one another along the first direction X and have respective lateral sides exposed flush with and outside the molded package structure 108 along the fifth side 105. In addition, the electronic device 100 has a second set of four instances of the second leads 109 that are spaced apart from one another along the first direction X and have respective lateral sides flush with and exposed outside the molded package structure 108 along the sixth side 106. The leads 107 and 109 in the illustrated example are or include copper, aluminum, or other suitable metal or alloys thereof. In the example of FIGS. 1 and 1A, the second leads 109 have a bottom side exposed outside the molded package structure 108 along the first side 101, and the second leads 109 have a uniform thickness along the third direction Z.

The electronic device 100 also includes a die attach pad 110, such as a conductive metal for example that is or includes copper, aluminum, or other suitable metal or alloys thereof, as well as one or more tie bars 111 connected to the die attach pad 110. In the illustrated example, the bottom side of the die attach pad 110 is substantially flush with the bottom or first side 101 of the electronic device 100, and the bottom side of the die attach pad 110 is exposed outside the molded package structure 108 along the first side 101, as best shown in FIG. 1A, for example, to operate as a heatsink or thermal pad when the electronic device 100 is installed in a host system. In another possible implementation, the bottom side of the die attach pad 110 is enclosed (e.g., covered) by the molded package structure 108. The illustrated example of FIGS. 1 and 1A includes half etch|structures 111 that are not exposed outside the bottom or first side 101 of the molded package structure 108. In this example, four tie bars 111 are contiguous with respective corners of the die attach pad 110 and are exposed outside the molded package structure 108 along respective ones of the fifth and sixth sides 105 and 106. In other implementations, fewer or more tie bars 111 have portions exposed outside the molded package structure 108 along one or both of the fifth and sixth sides 105 and 106.

In the illustrated example, first and second tie bars 111 are connected to the die attach pad 110 and exposed outside the molded package structure 108 along the fifth side 105 on opposite sides of the first set of the second leads 109 and spaced along the first direction X between the first set of the second leads 109 and the respective corners C1 and C2 as shown in FIGS. 1 and 1A. The first tie bar 111 in this example is exposed outside the molded package structure 108 along the fifth side 105 between the first corner C1 of the molded package structure 108 and the first set of the second leads 109, and the second tie bar 111 is exposed outside the molded package structure 108 along the fifth side 105 between the second corner C2 of the molded package structure 108 and the first set of the second leads 109.

The electronic device 100 in this example also includes third and fourth tie bars 111 exposed outside the molded package structure 108 along the sixth side 106 on opposite sides of the second set of the second leads 109 and spaced along the first direction X between the second leads 109 and the respective corners C3 and C4 as shown in FIG. 1. In this example, the third tie bar 111 is exposed outside the molded package structure 108 along the sixth side 106 between the third corner C3 of the molded package structure 108 and the second set of the second leads 109 and the fourth tie bar 111 is exposed outside the molded package structure 108 along the sixth side 106 between a fourth corner C4 of the molded package structure 108 and the second set of the second leads 109.

As shown in FIG. 1, the example electronic device 100 also includes a semiconductor die 114 mounted (e.g., attached) to a top side of the die attach pad 110 by a conductive or nonconductive adhesive layer 113. The semiconductor die 114 in this example includes conductive metal terminals (e.g., bond pads) on a top side thereof provide electrical terminal connections to one or more circuit components within the semiconductor die. In addition, the electronic device 100 includes electrical connections between one or more of the conductive metal terminals of the semiconductor die 114 and respective ones of the leads 107, 109. In the illustrated example, the semiconductor die 114 is electrically coupled to one of the first leads 107 and to at least one of the second leads 109 via conductive metal bond wires 116 as shown in FIG. 1. Other forms of electrical interconnection can be used, such as routable lead frames, single or multilevel substrates, etc. (not shown), alone or in combination with one or more bond wires 116.

The die attach pad 110, the tie bars 111, and the leads 107 and 109 in one example are formed of the same material, for example a conductive metal that is or includes copper, etc., and one or more of these structures are separated by punching, cutting, etching, etc. from a starting lead frame panel array during manufacturing. In one example, the starting lead frame panel array and one or more of the structures 107, 109-111 have or include step features, referred to as half etch features with different thicknesses along the third direction Z. In the example of FIGS. 1 and 1A, the first leads 107 have half etch features (e.g., cars enclosed by the molded package structure 108 as seen in FIG. 1A), and the tie bars 111 have a thickness along the third direction Z that is less than the thickness of the larger portions of the first leads 107. The first (e.g., stub) leads 107 and the second (e.g., flush) leads 109 have substantially uniform thickness is along the third direction Z.

FIGS. 1B and 1C show bottom perspective views of two different example hybrid quad flat package electronic devices with second (e.g., flush) leads having different half etch features and structures. These non-limiting examples include structures and features 101-108, 110, and 111 similar to those described above in connection with FIGS. 1 and 1A, as well as internal features (e.g., semiconductor die 114, die attach adhesive 113, bond wires 116, etc.) that are not shown in the bottom views of FIGS. 1B and 1C.

FIG. 1B shows another example electronic device 120 with first and second sets of second (e.g., flush) leads 129 along the opposite fifth and sixth sides 105 and 106 (e.g., lateral ends) as well as the above-described first (e.g., stub) leads 107 along the third and fourth sides 103 and 104 (e.g., along opposite lateral sides). In this example, the individual second leads 129 along the fifth and sixth sides 105 and 106 have a nonuniform thickness along the third direction Z and include a bottom side half etch pullback feature. The second leads 129 in FIG. 1B have bottom sides exposed outside of and substantially flush with the first (e.g., bottom) side 101 of the electronic device 120. The bottom sides of the second leads 129 are spaced apart from the sides of the package structure 108 by a second spacing distance D2 along the respective fifth and sixth sides 105 and 106. In addition, the portions of the second leads 129 exposed along the respective sides 105 and 106 are spaced apart from the bottom side 101 of the electronic device 120 and have a thickness along the third direction Z that is less than that of the stub leads 107. Internal portions of the second leads 129 in this example have thicker portions (not shown) that are approximately the same thickness as the first leads 107.

FIG. 1C shows another example electronic device 130 with flush or second leads 139 along opposite lateral ends (e.g., along the fifth and sixth sides 105 and 106) as well as first or stub leads 107 along the opposite third and fourth sides 103 and 104. The second leads 139 in this example have a nonuniform thickness along the third direction Z and include a top side half etch feature with no pullback. As shown in FIG. 1C, the bottom sides of the second leads 139 are flush with and exposed along the bottom or first side 101 of the electronic device 130, and the bottom sides of the second leads 139 extend to the sides of the package structure 108 along the respective fifth and sixth sides 105 and 106. In addition, the portions of the second leads 139 exposed along the respective sides 105 and 106 extend to the bottom or first side 101 of the electronic device 120 and have a thickness along the third direction Z (e.g., approximately 2.5 mils) that is less than that of the first or stub leads 107, and internal portions of the second leads 139 in this example have thicker portions (not shown) that are approximately the same thickness as the first leads 107 (e.g., approximately 5 mils).

The illustrated example electronic devices 100, 120, and 130 as well as other possible implementations advantageously provide the high I/O count and circuit density advantages of quad flat package integrated circuits and other electronic devices, while facilitating low cost manufacturing through the use of stub leads 107 in combination with flush leads 109, 129, and/or 139. In addition, the provision of the first or stub leads 107 allows solder connection to a host printed circuit board (not shown) where solder can wet along the sides of the first leads 107 and help optical or other inspection of surface mount technology (SMT) solder joint quality along the respective third and fourth sides 103 and 104, and the use of the first or stub leads 107 facilitates low-cost punch separation technology during electronic device manufacturing. In addition, the provision of the first or stub leads 107 can facilitate high throughput column separation by cost effective punching operations to further reduce cost compared to quad flat pack manufacturing with flush leads along four sides. Moreover, the use of half etch features (e.g., FIGS. 1B and/or FIG. 1C) provides a relatively thin metal structures of the second leads 129 and 139 to facilitate reduced wear of saw cutting equipment used in row direction package separation to cut through portions of the molded package structure 108, any included tie bars 111, and the ends of the conductive second leads 129 and 130.

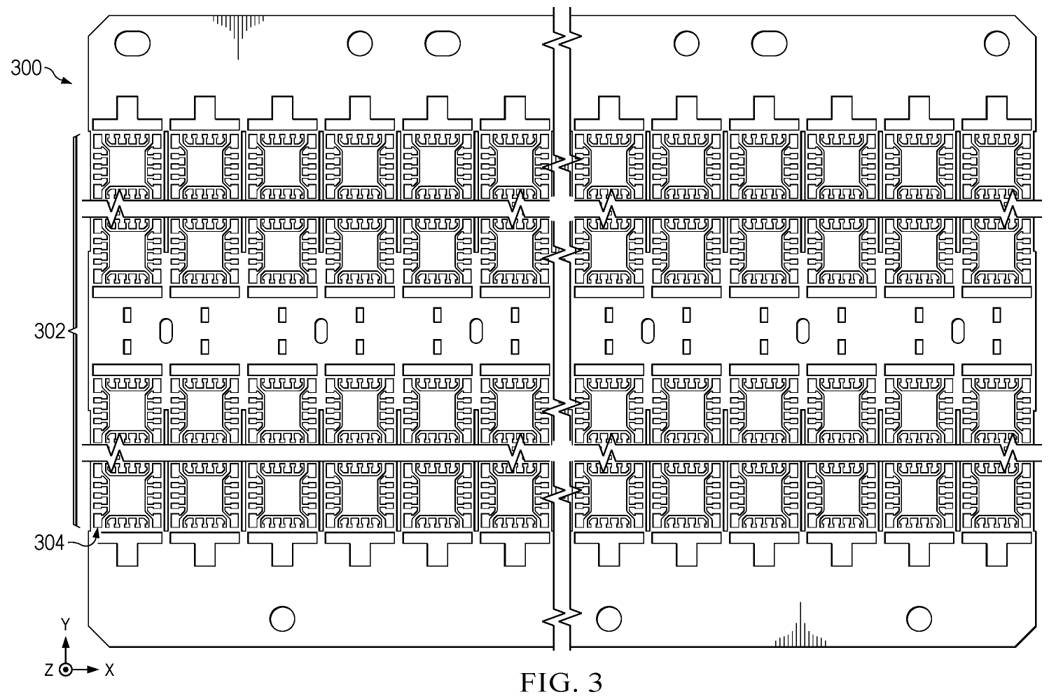

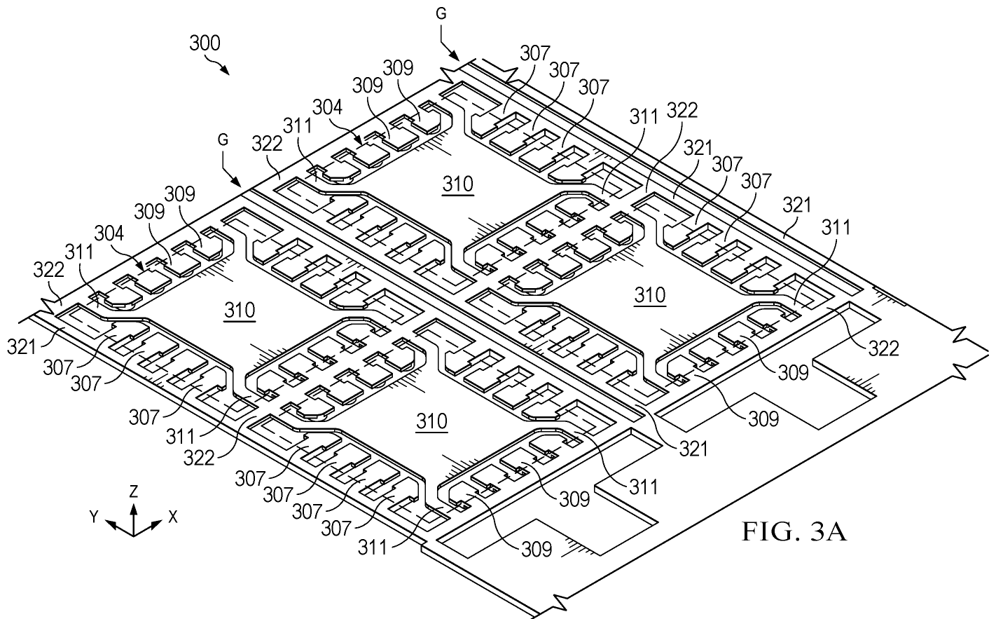

In combination, the use of the second (e.g., flush) leads 109, 129 and/or 139 advantageously allows column-wise molding during device fabrication and avoids the cost and complexity associated with film assisted molding used in conventional saw QFN manufacturing. In addition, the hybrid approach using a column-wise molding approach allows more units per lead frame array or strip to thereby facilitate reduced manufacturing cost. The illustrated examples can also benefit from half etch features in the original starting lead frame in order to facilitate mold locking and reduced delamination problems during manufacturing and in system use of the finished electronic device 100, 120, 130. The exposed internal tie bars 111, moreover, help support and stabilize the connected corners of the thermal pad or die attach pad 110 during manufacturing (e.g., prior to column and row direction separation operations described further below) and the positioning of the tie bars 111 proximate the corners C1-C4 of the finished electronic device facilitate high lead (e.g., I/O) density and usage. In addition, illustrated examples (e.g., FIGS. 3 and 3A below) can employ column direction slots or gaps G to improve throughput and reduce manufacturing cost while mitigating lead frame warpage during fabrication.

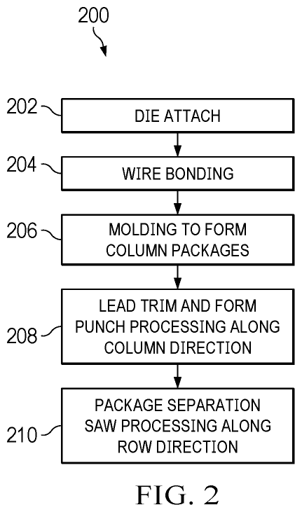

Referring now to FIGS. 2-8, FIG. 2 shows a method 200 for making an electronic device according to another aspect and FIGS. 3-8 shows the example electronic device 100 at various stages of fabrication according to the method 200. The method 200 is illustrated during processing that begins with a starting lead frame.

FIGS. 3 and 3A show an example starting lead frame 300 in the form of a panel array with conductive metal features (e.g., copper, aluminum, etc.) including upper and lower outer frames and an interior portion 302 (FIG. 3) with unit areas 304 formed in rows that extend along the illustrated first direction X and columns that extend along the orthogonal second direction Y. In one implementation, the lead frame 300 is designed for molding operations with a mold having column-wise cavities extending along the second direction Y to be filled from the bottom to the top or from the top to bottom in the orientation shown in FIG. 3. The lead frame 300 can be or include any suitable conductive metal, such as copper, aluminum, alloys thereof, etc. The lead frame 300 can be fabricated using any suitable processing techniques and equipment, including stamping, etching and/or combinations thereof to form the conductive metal structures.

The individual unit areas 304 can include one or more conductive metal features corresponding to prospective conductive leads as well as one or more die attach pad structures suitable for attachment of one or more semiconductor dies within the respective unit areas 304. The individual unit areas 304 in this example have a respective die attach pad to accommodate mounting of one or more semiconductor dies (not shown) during fabrication of individual packaged electronic devices in the respective unit areas 304. In addition, the individual unit areas 304 in this example have one or more conductive features spaced apart from the associated die attach pad which correspond to prospective leads of the finished electronic device as well as internal tie bars structures extending from corners of the die attach pad and further tie bars along the row and column directions between adjacent unit areas 304.

As shown in FIG. 3A, the individual unit areas 304 have prospective first leads 307 along two opposite lateral sides of the unit area 304 that are spaced apart from one another along the first direction X, and prospective second leads 309 along two opposite lateral ends of the unit area 304 that are spaced apart from one another along the second direction Y. The prospective leads in this example have lower surface that extend in a lead frame plane and her coplanar with one another to facilitate soldering of the finished electronic devices to a host circuit board (not shown).

In addition, the individual unit areas have a die attach pad 310 with four corners contiguous with and connected to tie bars 311. The lead frame 300 extends in a plane of the first and second directions X and Y, respectively (e.g., an X-Y plane) and bottom sides of the prospective lead structures are approximately coplanar with one another to facilitate subsequent soldering of a fabricated packaged electronic device to a host printed circuit board (not shown). The lead frame 300 in one example is a flat structure. In another example, the lead frame 300 includes one or more raised features, such as half etch features, for example, to accommodate die attach pad structures, tie bars, dam bars, etc. having bottom sides that are not coplanar with the bottom sides of the prospective leads.

The lead frame panel array 300 has first tie bars 321 that extend along the second direction Y between adjacent columns, and the respective first tie bars 321 are connected to the prospective first leads 307 of the unit areas 304 along a column of the array. The illustrated example, moreover, includes gaps G between adjacent pairs of the first tie bars 321, for example, to mitigate lead frame warping or deformation during handling in a manufacturing process. The lead frame 300 also includes second tie bars 322 that extend along the first direction X between adjacent rows of the array configuration, and the second tie bars 322 are connected to the prospective second leads 309 along adjacent rows of the array. The tie bars 311 (e.g., referred to as third tie bars) are individually connected between a corner of a respective die attach pad 310 and an adjacent one of the second tie bars 322 of the unit areas 304 along the column of the array.

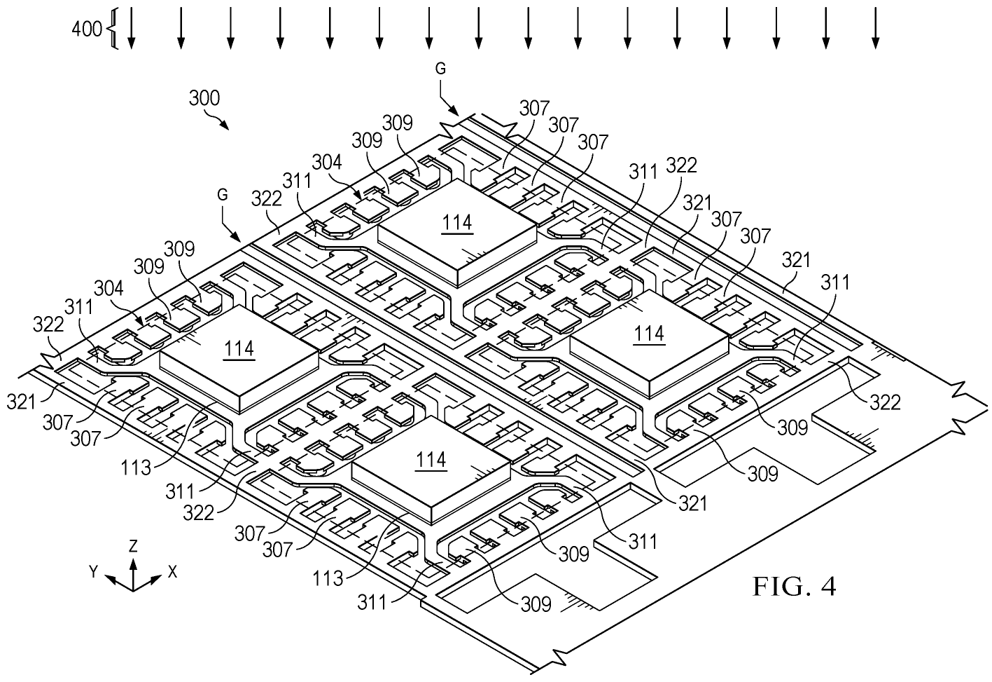

The method 200 begins with die attach processing at 202 in FIG. 2. FIG. 4 shows an example die attach process 400 performed using a starting lead frame 300. The example die attach process 400 mounts a semiconductor die 114 onto the associated die attach pad (e.g., die attach pads 310 in FIG. 3A above) in one or more of the individual unit areas 304 of the lead frame 300. The die attach process 300 can include, for example, dispensing, printing, or otherwise providing solder or conductive or nonconductive adhesive 113 in select portions of top sides of certain lead frame features, as well as placement of semiconductor dies 114 and/or passive components in corresponding locations on the solder paste or die attach adhesive 113 (e.g., using automated pick and place equipment, not shown), and subsequent solder reflow and/or curing processing (e.g., thermal reflow, thermal adhesive curing. UV adhesive curing, etc.) to adhere the semiconductor dies 114 to the corresponding locations of the lead frame panel array 300.

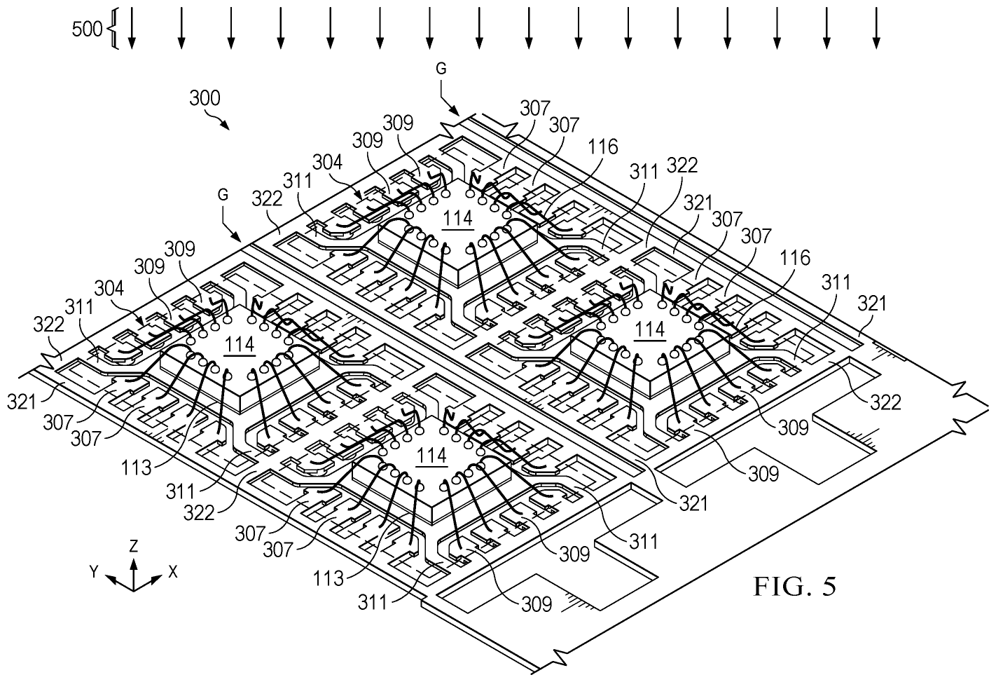

The method 200 continues at 204 with electrical connection of a circuit or a component of the individual semiconductor dies 114 to select ones of the first leads 307 and 309 in the individual unit areas 304. FIG. 5 shows one example, in which a wire bonding connection process 500 is performed that creates the bond wires 116 for the electrical circuit connections of the semiconductor dies 114 and respective conductive metal features corresponding to prospective leads 307 and 309 in each unit area 304 of the lead frame panel array 300. In another implementation, further and/or different bond wires (not shown) and/or soldered metal clips, substrates with routing connections, etc. (not shown) can be created and/or installed at 204, for example, to provide desired electrical circuit connections in each unit area 304. In the illustrated example, the bond wires 116 provide electrical connection of at least one conductive terminal (e.g., a copper or aluminum bond pad) of the respective semiconductor dies 114 to a conductive feature in the corresponding unit area 304 of the lead frame 300. The example wire bonding process 500 electrically connects the semiconductor die 114 to the prospective first leads along two opposite lateral sides of the unit areas 304 that are spaced apart from one another along the first direction X, and electrically connects the prospective second leads 309 along two opposite lateral ends of the unit area 304 that are spaced apart from one another along the second direction Y.

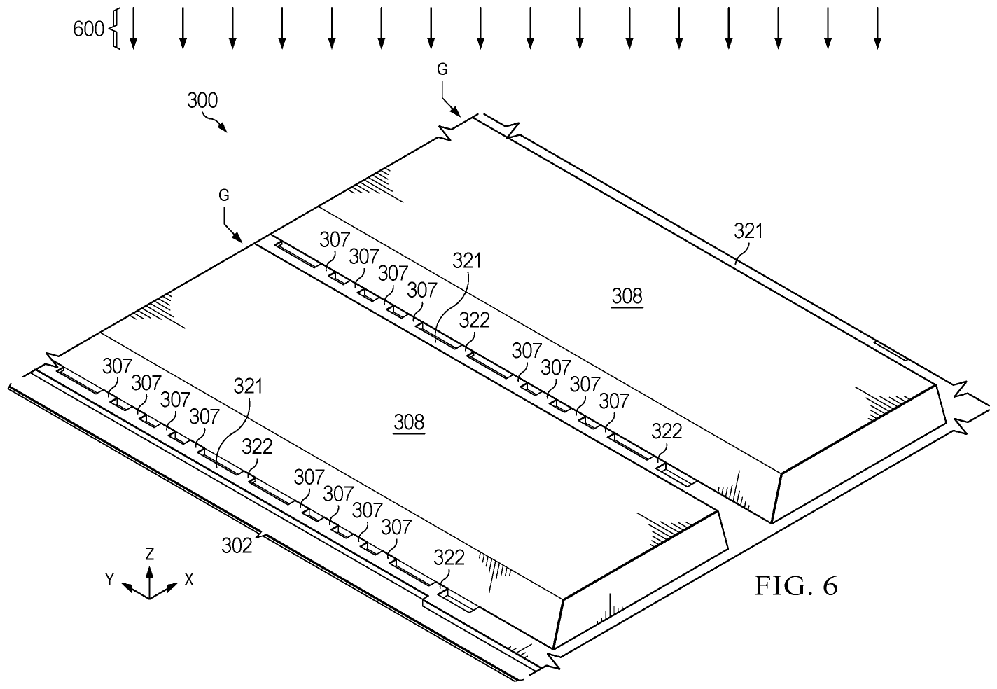

The method 200 continues at 206 in FIG. 2 with molding processing to form molded structures along columns of the lead frame panel array 300. FIG. 6 shows one example, in which a molding process 600 is performed using a mold (not shown) that forms a molded structure 308 (e.g., also referred to as a mold bar) along each of the columns of the lead frame panel array 300. The individual molded structures 308 extend through multiple unit areas 304 each respective column of the lead frame 300 over the semiconductor die 114 and the bond wires 116 in each unit area 304. In addition, the individual molded structures 308 expose portions of the prospective first (e.g., stub) leads 307 in each unit area 304, and enclose the prospective second (e.g., flush) leads 309 in the unit area 304. The structure 308 in this example encloses the upper portions of die attach pad 310 of each unit area 304 and does not enclose the bottom sides of the die attach pads 310, although not a requirement of all possible implementations.

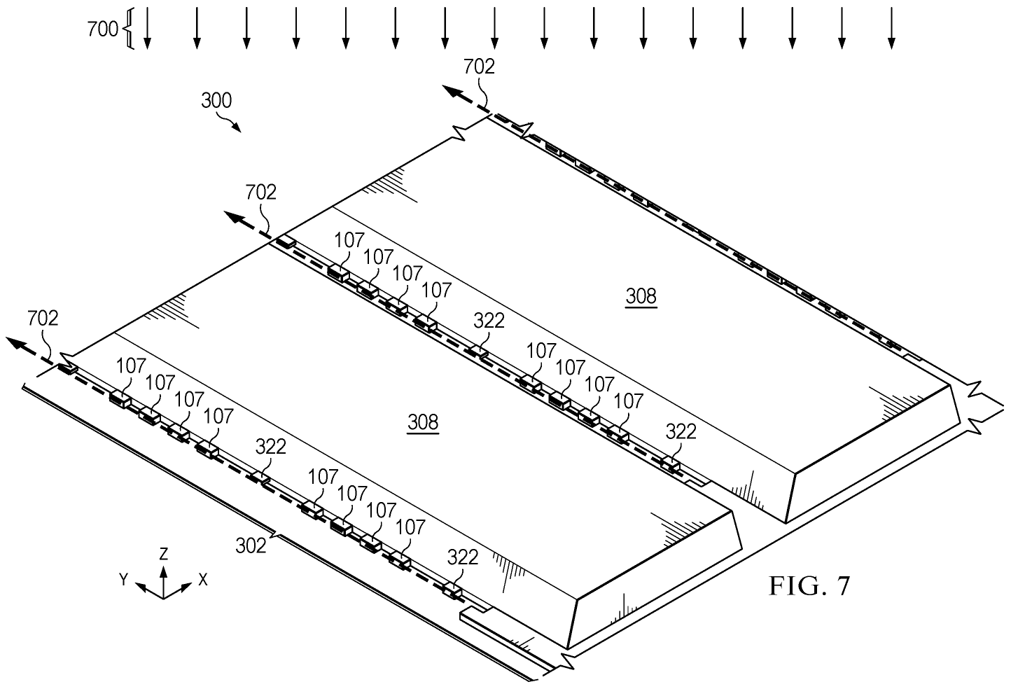

The method 200 continues at 208 in FIG. 2 with column direction package separation, in one example including lead trimming and optional lead forming. FIG. 7 shows one example, in which the separation process 700 is performed along lines 702 (e.g., along the second direction Y in the illustrated orientation) to separate adjacent columns of unit areas 304 from one another. In one example, the separation process 700 is or includes use of punch die equipment (not shown) that trims the prospective first leads 307 (e.g., FIGS. 3-6 above) that originally extended between laterally neighboring unit areas 304 to form the first (e.g., stub) leads 107 that extend outward from the lateral sides of the molded structures 308 along each column of the lead frame array 300.

In another example, the separation process 700 can include a saw blade cutting operation using one or more cutting blades (not shown), such as a single cutting blade performing one cut at a time along the respective lines 702. In another implementation, laser cutting and/or other separation steps can be used alone or in combination with punching or other operations to perform single or multiple pass separation along the lines 702.

In these or another example, the separation process 700 can include punching operations and/or other processing to form separated leads along the lateral sides of the unit areas 304 into a desired shape, such as j-leads, gullwing leads, etc. (not shown). In the above or another implementation, the method can include optional plating operations after lead trimming and forming at 208, for example, to plate the exposed surfaces of the trimmed first leads 107 and the bottoms of the prospective second leads 309 (FIGS. 3-5 above) to provide fully and/or partially plated leads in the finished electronic device of each unit area 304. The separation process 700 in this example separates each individual column from an adjacent second column of the lead frame 300 along the second direction Y to form first leads 107 along the two opposite lateral sides of the individual unit areas 304.

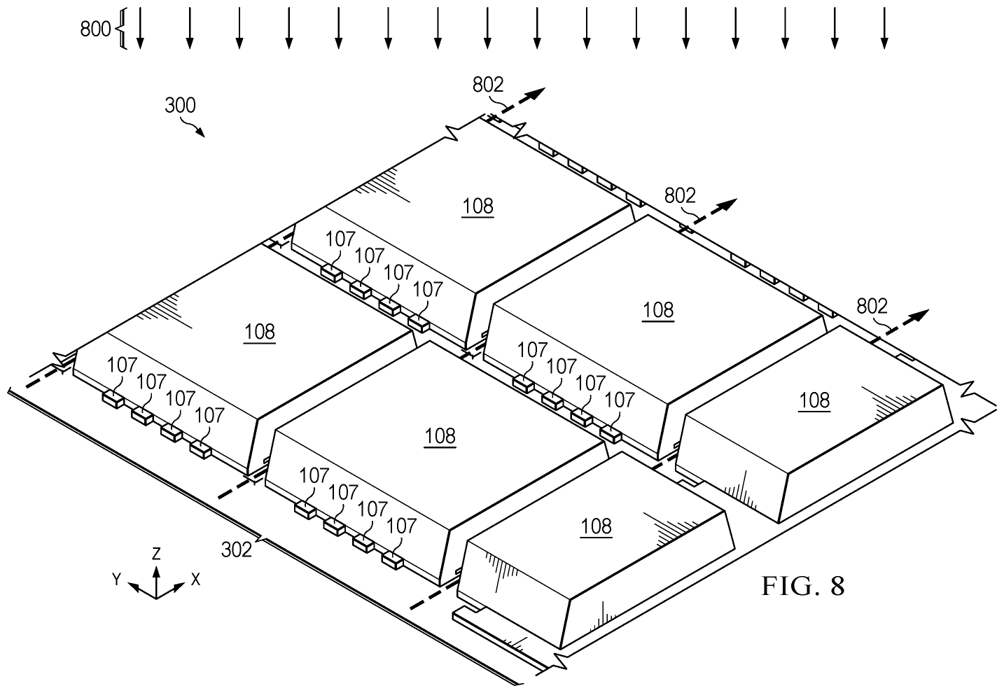

The method 200 continues at 210 in FIG. 2 with row direction package separation to separate individual packaged electronic devices from one another along each column in the array. FIG. 8 shows one example, in which a separation process 800 is performed (e.g., saw blade cutting, laser cutting, chemical etching, combinations thereof, etc.). The separation process 800 separates finished packaged electronic devices 100 and adjacent rows and unit areas 304 of each column from one another and from the lead frame 300 along lines 802 (e.g., along the first direction X). In one example, the separation process 800 includes a saw or laser cutting process 800 that cuts through the molded structure 308 and the prospective second leads 309 to form the second leads 109 (e.g., the flush leads) along the two opposite lateral ends of the unit area 304 which separates each molded structure 308 into individual molded packages structures 108.

The example method 200 and the illustrated electronic devices 100, 120, 130 provides a solution to quad flat package production cost challenges and provide a hybrid quad flat package with stub leads along the third and fourth sides 103 and 104 as well as flush leads along the fifth and sixth sides 105 and 106, respectively. The method 200, moreover, can provide improved separation throughput rates and reduced equipment wear and replacement cost as well as simplifying and reducing molding cost and complexity without requiring film assisted molding or custom molds for different product sizes, in addition to potentially increased panel device density (e.g., more unit areas per panel array or strip). In addition to cost reduction benefits, the inclusion of the first or stub leads 107 provides solder sidewall wetting that enables post SMT assembly solder joint inspection, for example, using automated optical sensors in a variety of and use applications such as industrial and/or automotive systems. Moreover, the hybrid electronic device footprint is the same as that of prior quad flat devices (e.g., QFN) and allows the hybrid electronic devices 100, 120, 130 to be used in existing printed circuit boards, QFN sockets or other host systems.

Modifications are possible in the described examples, and other implementations are possible, within the scope of the claims.

What is claimed is:

1. An electronic device, comprising:
opposite first and second sides;
opposite third and fourth sides spaced apart from one another along a first direction;
opposite fifth and sixth sides spaced apart from one another along a second direction that is orthogonal to the first direction, the first and second sides spaced apart from one another along a third direction that is orthogonal to the first and second directions;
a molded package structure;
conductive metal first leads exposed outside the molded package structure along the first side, and individual ones of the first leads extending outward from the molded package structure along a respective one of the third and fourth sides; and
conductive metal second leads exposed outside the molded package structure along the first side, individual ones of the second leads having a lateral side exposed outside the molded package structure along a respective one of the fifth and sixth sides, and the lateral side of the individual second leads being flush with a respective side of the molded package structure along the respective one of the fifth and sixth sides.

2. The electronic device of claim 1, comprising:
a die attach pad; and
a tie bar connected to the die attach pad and exposed outside the molded package structure along the fifth side.

3. The electronic device of claim 2, comprising a second tie bar spaced apart from the tie bar and exposed outside the molded package structure along the fifth side.

4. The electronic device of claim 3, comprising:
a third tie bar exposed outside the molded package structure along the sixth side; and
a fourth tie bar spaced apart from the third tie bar and exposed outside the molded package structure along the sixth side.

5. The electronic device of claim 4, wherein:
a first set of the second leads are spaced apart from one another along the first direction and have respective lateral sides exposed outside the molded package structure along the fifth side;
the tie bar is exposed outside the molded package structure along the fifth side between a first corner of the molded package structure and the first set of the second leads;
the second tie bar is exposed outside the molded package structure along the fifth side between a second corner of the molded package structure and the first set of the second leads;
a second set of the second leads are spaced apart from one another along the first direction and have respective lateral sides exposed outside the molded package structure along the sixth side;
the third tie bar is exposed outside the molded package structure along the sixth side between a third corner of the molded package structure and the second set of the second leads; and
the fourth tie bar is exposed outside the molded package structure along the sixth side between a fourth corner of the molded package structure and the second set of the second leads.

6. The electronic device of claim 2, wherein:
a first set of the second leads are spaced apart from one another along the first direction and have respective lateral sides exposed outside the molded package structure along the fifth side; and
a second set of the second leads are spaced apart from one another along the first direction and have respective lateral sides exposed outside the molded package structure along the sixth side.

7. The electronic device of claim 6, wherein:
a first set of the first leads are spaced apart from one another along the second direction and have respective lateral sides exposed outside the molded package structure along the third side; and
a second set the first leads are spaced apart from one another along the second direction and have respective lateral sides exposed outside the molded package structure along the fourth side.

8. The electronic device of claim 2, comprising a semiconductor die electrically coupled to one of the first leads and to one of the second leads.

9. The electronic device of claim 1, wherein:
a first set of the second leads are spaced apart from one another along the first direction and have respective lateral sides exposed outside the molded package structure along the fifth side; and
a second set of the second leads are spaced apart from one another along the first direction and have respective lateral sides exposed outside the molded package structure along the sixth side.

10. The electronic device of claim 9, wherein:
a first set of the first leads are spaced apart from one another along the second direction and have respective lateral sides exposed outside the molded package structure along the third side; and
a second set the first leads are spaced apart from one another along the second direction and have respective lateral sides exposed outside the molded package structure along the fourth side.

11. The electronic device of claim 1, wherein:
a first set of the first leads are spaced apart from one another along the second direction and have respective lateral sides exposed outside the molded package structure along the third side; and
a second set the first leads are spaced apart from one another along the second direction and have respective lateral sides exposed outside the molded package structure along the fourth side.

12. The electronic device of claim 1, comprising a semiconductor die electrically coupled to one of the first leads and to one of the second leads.

13. The electronic device of claim 1, wherein the second leads have a bottom side exposed outside the molded package structure along the first side, and the second leads have a uniform thickness along the third direction.

14. The electronic device of claim 1, wherein the second leads have a nonuniform thickness along the third direction and include a bottom side half etch pullback feature.

15. The electronic device of claim 1, wherein the second leads have a nonuniform thickness along the third direction and include a top side half etch feature with no pullback.

16. A method of fabricating an electronic device, the method comprising:
mounting a semiconductor die in a unit area of a lead frame;
electrically connecting the semiconductor die to prospective first leads along two opposite lateral sides of the unit area that are spaced apart from one another along a first direction;
electrically connecting the semiconductor die to prospective second leads along two opposite lateral ends of the unit area that are spaced apart from one another along a second direction that is orthogonal to the first direction;
forming a molded package structure that extends through multiple unit areas along a column of the lead frame, exposes portions of the prospective first leads in the unit area, and encloses the prospective second leads in the unit area;
separating the column from an adjacent second column of the lead frame along the second direction to form first leads along the two opposite lateral sides of the unit area; and
separating an electronic device of the unit area from the lead frame along the first direction to cut through the molded package structure and the prospective second leads to form second leads along the two opposite lateral ends of the unit area.

17. The method of claim 16, wherein the lead frame has a thickness of 0.1 mm or more and 3.0 mm or less, and separating the column from an adjacent second column of the lead frame includes performing a punching process that forms the first leads along the two opposite lateral sides of the unit area.

18. The method of claim 17, wherein separating an electronic device of the unit area from the lead frame includes performing a saw or laser cutting process that cuts through the molded package structure and the prospective second leads to form the second leads along the two opposite lateral ends of the unit area.

19. The method of claim 16, wherein:
the electronic device has a package size of 1.2 mm×1.2 mm or more and 20 mm×20 mm or less;
the electronic device has a package thickness of 0.25 mm or more and 5.0 mm or less; and
separating an electronic device of the unit area from the lead frame includes performing a saw or laser cutting process that cuts through the molded package structure and the prospective second leads to form the second leads along the two opposite lateral ends of the unit area.

20. A lead frame, comprising:
unit areas arranged in an array with rows along a first direction and columns along an orthogonal second direction, the respective unit areas having a die attach pad, prospective first leads along two opposite lateral sides of the unit area that are spaced apart from one another along the first direction, and prospective second leads along two opposite lateral ends of the unit area that are spaced apart from one another along the second direction;
first tie bars connected to the prospective first leads of the unit areas along a column of the array;
second tie bars connected to the prospective second leads along adjacent rows of the array; and
third tie bars connected between the die attach pad and an adjacent one of the second tie bars of the unit areas along the column of the array.
